(19) United States
(12) Patent Application Publication
(10) Pub. No.: US 2012/0235213 A1
(43) Pub. Date: Sep. 20, 2012

(54) SEMICONDUCTOR STRUCTURE WITH A STRESSED LAYER IN THE CHANNEL AND METHOD FOR FORMING THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignee: INSTITUTE OF MICROELECTRONICS, CHINESE ACADEMY OF SCIENCES, Beijing (CN)

(21) Appl. No.: 12/996,673

(22) PCT Filed: Jun. 24, 2010
(86) PCT No.: PCT/CN10/74388

§ 371 Date: Dec. 7, 2010

(30) Foreign Application Priority Data
Dec. 23, 2009 (CN) 200910243852.2

(51) Int. Cl. H01L 21/336; H01L 29/78

(52) U.S. Cl. 257/288; 438/290; 257/E29.255; 257/E21.444

(57) ABSTRACT

The present invention provides a semiconductor structure with a stressed layer in the channel and method for forming the same. The semiconductor structure comprises a substrate; a gate stack, including a gate dielectric layer formed over the substrate, gate layer formed over the gate dielectric layer, a source region and a drain region formed in the substrate by both sides of the gate stack; one or more spacers formed on both sides of the gate stack; and an embedded stressed layer formed under the gate stack in the substrate. In the embodiments of the present invention, the carrier mobility can be effectively increased by the embedded stressed layer added in the channel under the gate stack, so that the driving current of transistors is improved. Moreover, the technological process for forming this embedded stressed layer in the present invention has a lower thermal budget, which therefore assists in maintaining a higher stress level in the channel region. Besides, apart from the advantage in the aspect of stress, the embedded stressed layer in the channel can further decrease the diffusion/invasion of B (boron) from the heavily doped source and drain regions.

### TECHNICAL FIELD

The present invention relates to the field of semiconductor manufacturing, in particular, to a semiconductor structure with a stressed layer in channel and method for forming the same.

### BACKGROUND OF INVENTION

The increasing requirements of performance and cost for the integrated circuit have caused the scale of elements of the integrated circuit elements to be drastically reduced in size and have continuously increased number of devices on the chip. With the incessant decreasing of the scale of the elements of the integrated circuit elements, many improvements have been made in the design of the integrated circuit transistors to maintain suitable levels of performance of these elements. For example, lightly doped structures (LDD), halo doping and graded impurity profiles are employed to counteract the short channel effect and the punch-through effects. A principal factor in maintaining a perfect performance in field effect transistors is the carrier mobility which may affect the amount of current or number of charges which may flow in the doped semiconductor channel. After the CMOS technique of 90 nm, the stress technique is used to increase the stress so as to increase the carrier mobility and to ultimately increase the driving current of the device. Mechanical stress in the channel region can increase or decrease carrier mobility significantly, depending on the sign of the stress (e.g. tensile or compressive) and the carrier type (e.g. electron or hole). For example, in the Chinese patent application No. 200410087007.8, published on May 4, 2005, entitled “Structure and Method to Regulate Carrier Mobility in Semiconductor Device”, FIG. 1 is the schematic view of the semiconductor structure of this application. In the process of manufacturing CMOS transistors in this application, the carrier mobility is enhanced or otherwise regulated by layering different stressed films over CMOS transistors; thereby the performance of the integrated circuit is improved.

Though the above application discloses a solution for improving the carrier mobility by laying the stressed films that is capable of improving the carrier mobility, it has its own disadvantages for its structure is complex and is not adapted to the widely used manufacturing procedure.

### SUMMARY OF THE INVENTION

The objective of the present invention is to solve one of the above problems; in particular, through the present invention the carrier mobility can be adjusted so as to improve the driving current of transistors.

In order to achieve the above objectives, in the first aspect of the present invention, a semiconductor structure with a stressed layer in the channel comprises: a substrate, a gate dielectric layer formed over the substrate, a gate layer formed over the gate dielectric layer, a source region and a drain region formed in the substrate by both sides of the gate layer; one or more spacers formed on both sides of the gate dielectric layer and gate layer; and an embedded stressed layer formed under the gate layer in the substrate.

In one embodiment of the present invention, if the semiconductor structure is PFET, the embedded stressed layer comprises Si:C. In another embodiment of the present invention, if the semiconductor structure is NFET, the embedded stressed layer comprises SiGe.

In one embodiment of the present invention, the gate dielectric layer comprises high-k gate dielectric materials.

In one embodiment of the present invention, the gate layer is formed of metal or polysilicon.

In another aspect of the present invention, a method for forming the semiconductor structure includes the following steps: providing a substrate; forming a gate dielectric layer and a gate layer on the substrate; forming one or more spacers on the both sides of the gate dielectric layer and the gate layer; forming a source region and a drain region in the substrate; removing the gate layer and forming an embedded stressed layer under the gate layer by implantation; and re-forming the gate layer.

In one embodiment of the present invention, the removing of the gate layer comprises additionally removing the gate dielectric.

In one embodiment of the present invention, the step of forming the embedded stressed layer under the gate layer by implantation includes: if the semiconductor structure is PFET, C is implanted to form an embedded stressed layer that comprises Si:C, and in another embodiment of the present invention, if the semiconductor structure is NFET, Ge is implanted to form an embedded stressed layer that comprises SiGe.

In one embodiment of the present invention, the gate dielectric layer comprises high-k gate dielectric materials.

In one embodiment of the present invention, the gate layer is formed of metal or polysilicon.

In the above embodiments, prior to forming the embedded stressed layer under the gate layer, the high temperature annealing can be further performed for the source and the drain region.

In the above embodiments, after forming the embedded stressed layer under the gate layer, the annealing can be further performed on the embedded stressed layer in ms grade and a shorter period of time, for example, laser annealing or flash annealing.

In the embodiments of the present invention, the carrier mobility can be effectively increased by the embedded stressed layer added in the channel under the gate stack, so that the driving current of transistors is improved. Moreover, the technological process for forming this embedded stressed layer in the present invention has a lower thermal budget, which therefore assists in maintaining a higher stress level in the channel region. Besides, apart from the advantage in the aspect of stress, the embedded stressed layer in the channel can further decrease the diffusion/invasion of B (boron) from the heavily doped source and drain regions.

The additional aspects and advantages of the present invention will be given in the following descriptions, partially become apparent in the descriptions or appreciated from the practice of the present invention.

### BRIEF DESCRIPTION OF DRAWINGS

The above and/or additional aspects and advantages of the present invention will be more apparently and better understood from the following descriptions of the embodiments with reference to the drawings, in which:

FIG. 1 is a schematic view of the semiconductor structure of the prior art;

FIG. 2 is a structural diagram of the semiconductor structure with the stressed layer in the channel according to the embodiments of the present invention; and

FIGS. 3-10 are cross sectional views of intermediate steps in the method for forming the above semiconductor structure according to the embodiments of the present invention.

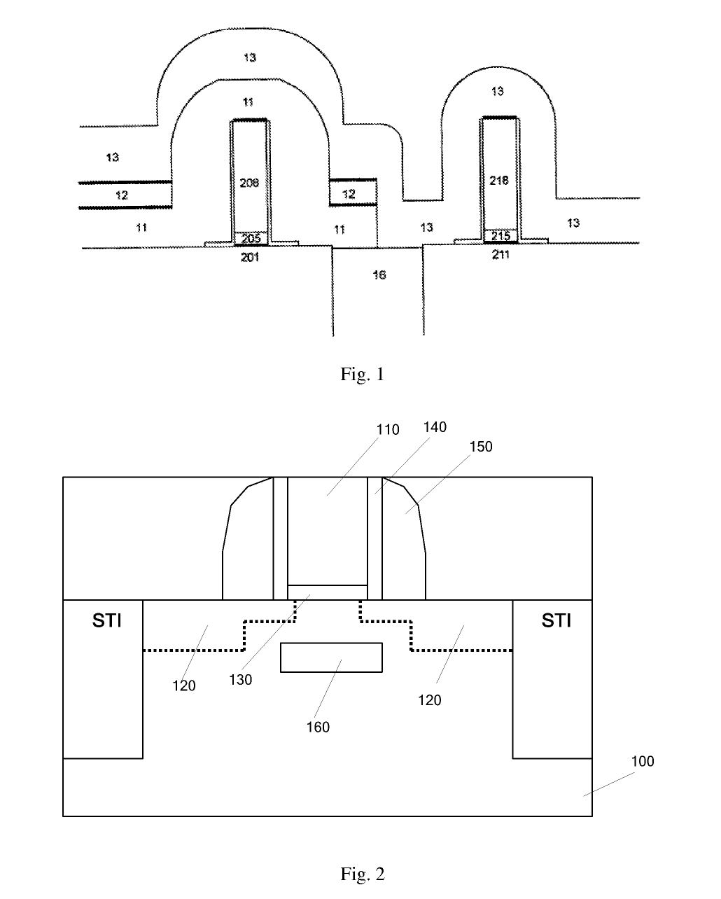

### DETAILED DESCRIPTION

The embodiments of the present invention will be described in detail below. The examples of the embodiments are shown in the accompanying drawings, in which the same or similar reference number represents the same or similar element or element having the same or similar function throughout the specification. The embodiments to be described with reference to the accompanying drawings are illustrative, are only for explaining the present invention but should not be construed as limiting the present invention.

The present invention is mainly to form in the channel under the gate stack a stressed layer that can effectively increase the carrier mobility so as to improve the driving current of the transistor. FIG. 2 shows the structural diagram of the semiconductor structure with a stressed layer in the channel according to one embodiment. The semiconductor structure of the embodiment includes a substrate 100, a gate dielectric layer 130 formed on the substrate 100. In other embodiment of the present invention, the gate dielectric layer 130 can be gate dielectrics with a high k-value. The structure also comprises a gate layer 110 formed on the gate dielectric layer 130, a source and drain regions 120 formed in the substrate 100 on both sides of the gate layer, and one or more sidewall spacers formed on both sides of the gate dielectric layer 130 and gate layer 110. In one embodiment, the sidewall spacers comprise the first spacers 140 and the second spacers 150 formed on the first sidewalls 140. In addition, in one embodiment, the gate layer 110 can be metal gates or polysilicon gates or combination of both. In order to increase the stress, the semiconductor structures in the embodiments of the present invention further comprise an embedded stressed layer 160 in the channel under the gate layer. The embedded stressed layer 160 can be formed by implanting different doping materials according to the different types of the FET tubes, for instance, if the semiconductor structure is PFET, C can be implanted to form an embedded stressed layer 160 that comprises Si:C; otherwise, if the semiconductor structure is NFET, Ge can be implanted to form an embedded stressed layer 160 that comprises SiGe. The embedded stressed layer 160 can improve the carrier mobility so as to enhance the driving current of the transistor. Moreover, apart from the advantage in the aspect of stress, the embedded stressed layer 160 according to the embodiments of the present invention further can decrease the diffusion/invasion of B (boron) from the heavily doped source and drain regions.

In other embodiment, the examples of the method for forming the above semiconductor structure are also provided in order to make the structure of the above semiconductor structure more clearly. It should be noted that different processes for manufacturing the above semiconductor structure, for example, product lines of different types, different technological processes, etc. can be selected for one skilled in the art. These different processes should also be covered in the protection scope of the present invention as long as the semiconductor structure, fabricated by these processes, has the structures substantially the same as the above in the present invention and achieves substantially identical effects. In order to understand the present invention more clearly, the method and process for forming the above structures of the present invention will be described in detail below. And it also should be pointed out that the following steps are merely illustrative without limiting the present invention, and can be accomplished with some other processes for one skilled in the art.

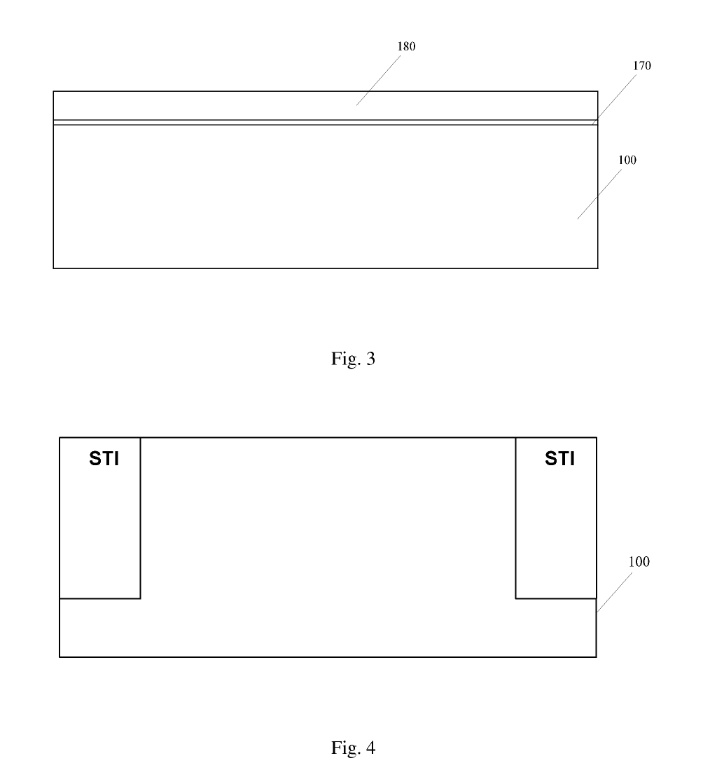

FIGS. 3-10 are cross sectional views of intermediate steps in the method for forming the above semiconductor structure in the embodiments of the present invention. The method includes the following steps:

In Step 1, as shown in FIG. 3, the substrate 100 is provided. The substrate 100 is formed with the oxide layer 170 and the nitride layer 180 thereon.

In Step 2, as shown in FIG. 4, the oxide layer 170 and the nitride layer 180 are etched, and STI (shallow trench isolation) with the desired depth is formed.

In Step 3, as shown in FIG. 5, the gate stack is formed via pattern etching over the substrate 100, for instance, depositing or growing the gate dielectric layer 130 over the substrate 100, and depositing the replacement gate 190. In this embodiment, the nitride coating layer 200 is further formed on the replacement gate 190 to protect the replacement gate 190. In this embodiment, the replacement gate 190 is formed by polysilicon, and in other embodiments, the replacement gate 190 also can be metal gate.

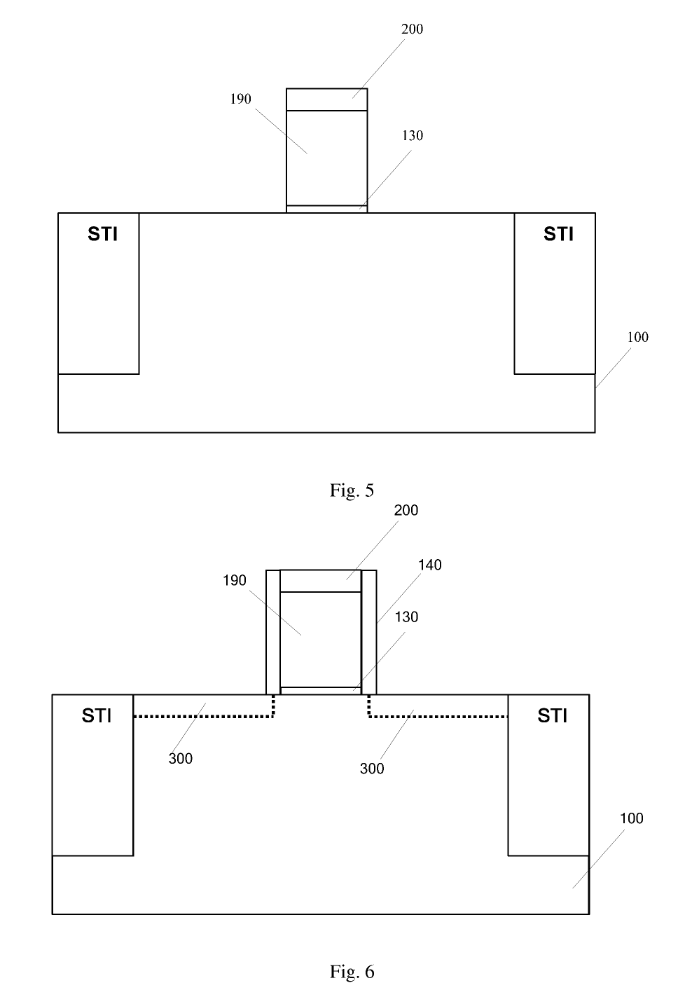

In Step 4, as shown in FIG. 6, the first spacers 140 are formed on both sides of the gate stack, and the extending/halo source and drain region 300 is formed by implantation.

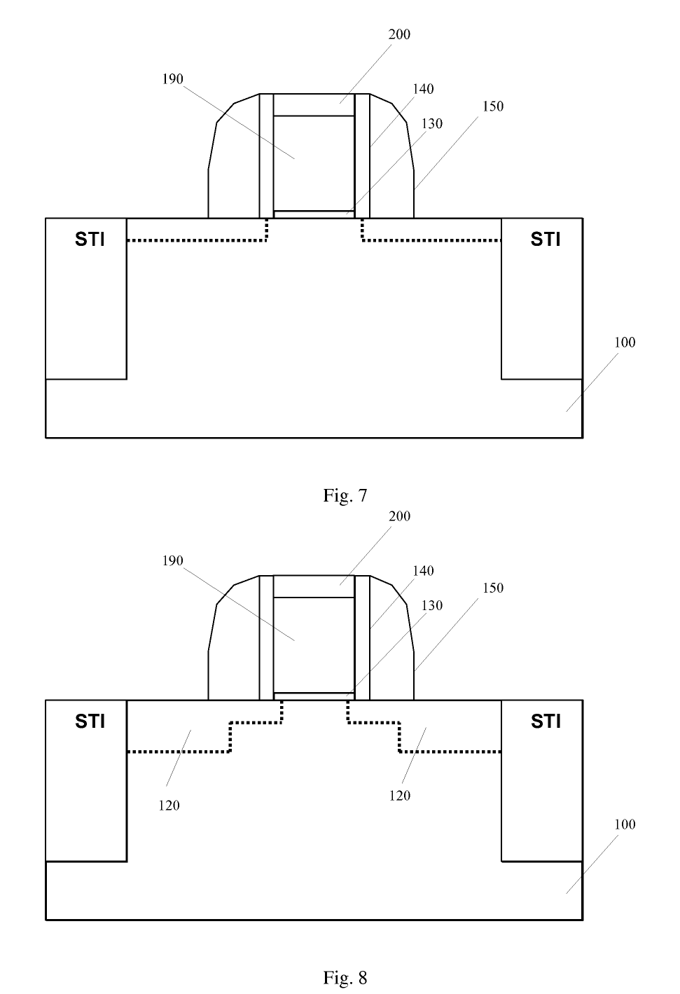

In Step 5, as shown in FIG. 7, the second spacers 150 are formed. In this embodiment, the first spacers 140 and the second spacers 150 are formed on both sides of the gate stack, which is merely one embodiment of the present invention, and the one skilled therein can increase or decrease the number of the spacers according to the actual requirements, which does not affect the accomplishment of the present invention and should be included in the protection scope of the present invention.

In Step 6, as shown in FIG. 8, the source and drain region 120 are formed by implantation. Selectively, the high temperature annealing also can be performed.

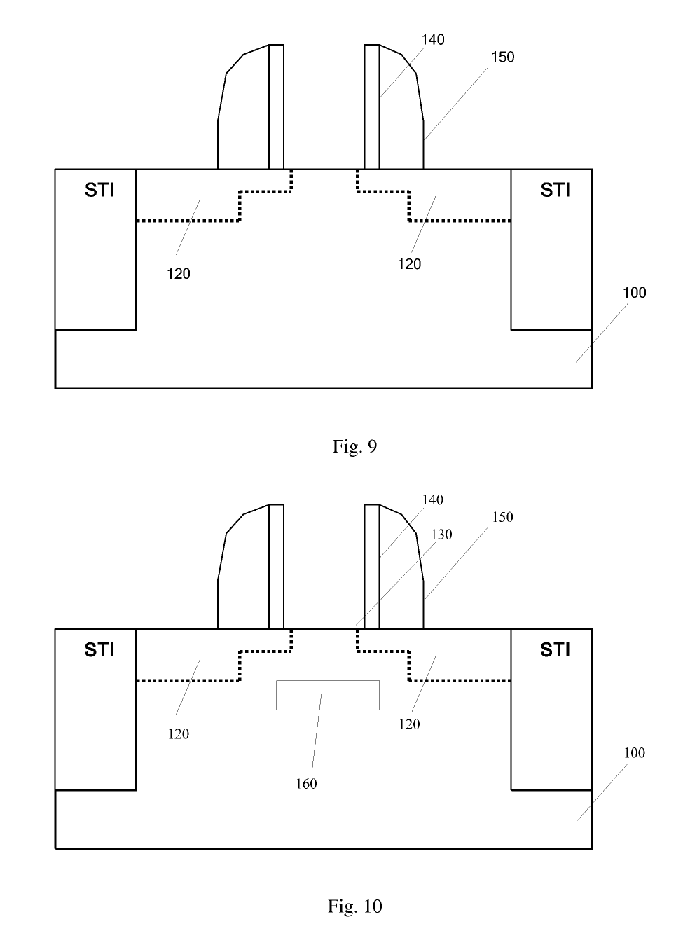

In Step 7, as shown in FIG. 9, the replacement gate 190 and the nitride coating layer 200 are removed. Selectively, in one embodiment of the present invention, the gate dielectric layer 130 can be removed along with the replacement gate layer 190.

In Step 8, as shown in FIG. 10, the embedded stressed layer 160 is formed by implantation, and the annealing, for example, laser annealing or flash annealing is performed in ms grade or a shorter period of time. In the present invention, if the semiconductor structure is PFET, C is implanted to form an embedded stressed layer 160 that comprises Si:C, and in another embodiment of the present invention, if the semiconductor structure is NFET, Ge is implanted to form an embedded stressed layer 160 that comprises SiGe. This stressed layer can further decrease the diffusion/invasion of B (boron) from the heavily doped source and drain regions.

In Step 9, the gate stack is formed again using appropriate gate replacement process. The re-made gate layer 110 in this embodiment is metal gate layer, and the final structure is as shown in FIG. 2. In addition, if the gate dielectric layer 130 is removed in step 7, the gate dielectric layer 130 should be re-grown in this step.

In the embodiments of the present invention, the carrier mobility can be effectively increased by the embedded stressed layer added in the channel under the gate stack, so that the driving current of the transistors is improved. Moreover, the technological process for forming this embedded stressed layer in the present invention has a lower thermal budget, which therefore assists in maintaining a higher stress level in the channel region. Besides, apart from the advantage in the aspect of stress, the embedded stressed layer in the channel can further decrease the diffusion/invasion of B (boron) from the heavily doped source and drain regions.

While the embodiments of the present invention are illustrated and described, the person ordinarily skilled therein should appreciate that various changes, alterations, replacements and modifications, without departing from the principle and spirit of the present invention, can be made to these embodiments, and the scope of the present invention is defined by the appended claims and equivalent thereof.

1. A semiconductor structure with a stressed layer in the channel, comprising:
a substrate;
a gate stack, including a gate dielectric layer formed over the substrate and a gate layer formed over the gate dielectric layer;
a source region and a drain region formed in the substrate by the both sides of the gate stack;
one or more spacers formed on both sides of the gate stack; and
an embedded stressed layer formed under the gate stack in the substrate.

2. The semiconductor structure of claim 1, wherein
if the semiconductor structure is a PFET, the embedded stressed layer comprises Si:C; and
if the semiconductor structure is an NFET, the embedded stressed layer comprises SiGe.

3. The semiconductor structure of claim 1, wherein
the gate dielectric layer comprises high-k gate dielectric materials.

4. The semiconductor structure of claim 1, wherein
the gate layer is formed of metal or polysilicon.

5. A method for forming a semiconductor structure, including the following steps:
providing a substrate;
forming a gate stack comprising a dielectric layer and a gate layer on the substrate;
forming one or more spacers on both sides of the gate stack;
forming a source region and a drain region in the substrate;
removing the gate layer and forming an embedded stressed layer under the gate stack by implantation; and
re-forming the gate layer.

6. The method for forming the semiconductor structure of claim 5, wherein
the removing of the gate layer comprises additionally removing the gate dielectric.

7. The method for forming the semiconductor structure of claim 5, the step of forming the embedded stressed layer under the gate stack by the implantation includes:
if the semiconductor structure is a PFET, C is implanted to form an embedded stressed layer comprising Si:C, and
if the semiconductor structure is an NFET, Ge is implanted to form an embedded stressed layer comprising SiGe.

8. The method for forming the semiconductor structure of claim 5, wherein the gate dielectric layer comprises high-k gate dielectric materials.

9. The method for forming the semiconductor structure of claim 5, wherein the gate layer is formed of metal or polysilicon.

10. The method for forming the semiconductor structure of claim 5, prior to forming the embedded stressed layer under the gate stack, further comprising
performing a high temperature annealing on the source region and the drain region.

11. The method for forming the semiconductor structure of claim 5, after forming the embedded stressed layer under the gate stack, further comprising
annealing the embedded stressed layer in ms grade or a shorter period of time.

12. The method for forming the semiconductor structure of claim 11, wherein the annealing is laser annealing or flash annealing.
